(19) United States
(12) Patent Application Publication
(10) Pub. No.: US 2024/0222471 A1
(43) Pub. Date: Jul. 4, 2024

(54) Warpage Control of Component Carrier with Dummy Components

(71) Applicant: AT & S Austria Technologie & Systemtechnik AG, Leoben (AT)

(72) Inventors: Qi Tao, Leoben (AT); Thomas Krivec, Zeltweg (AT)

(21) Appl. No.: 18/090,120

(22) Filed: Dec. 28, 2022

(51) Int. Cl. H01L 29/66; H01L 21/67; H01L 25/065

(52) U.S. Cl. CPC H01L 29/66545; H01L 21/67288; H01L 25/0652; H01L 2924/3511

(57) ABSTRACT

A component carrier may include a stack comprising a plurality of stacked layers, the stacked layers comprising at least one electrically conductive layer structure and at least one electrically insulating layer structure; a plurality of equally designed electronic units formed in the stack, each electronic unit comprising at least one semiconductor element embedded into the stack, wherein each semiconductor element is made of a semiconductor material; wherein at least a plurality of said electronic units are arranged to form at least one active area, which is surrounded by a frame area without functional components; and a plurality of dummy components embedded into the stack in the frame area; wherein the at least a plurality of said electronic units is arranged in the at least one active area in a pattern comprising more than 2 rows and more than 2 columns.

### BACKGROUND INFORMATION

When embedding electronic components made of silicon or ceramics into an electrically insulating material e.g. prepreg or laminate build-up (in the following called component carrier) during a chip embedding process, additional inhomogeneities are introduced into the structure. The embedded silicon or ceramic chips show different thermomechanical properties causing locally anisotropic material behavior. Especially the thermal expansion behavior is to be considered as crucial. The properties of the embedded chips show a low CTE (coefficient of thermal expansion) combined with a rather isotropic expansion, while behavior of the laminates show overall significantly higher CTE with an orthotropic expansion behavior.

Commonly, during the chip embedding production process, the component carrier to be produced is laid up at room temperature. The chips are embedded into an interior layer of the component carrier and then the whole structure is cured in a lamination process at elevated temperatures, e.g. at 180° C. to 250° C. After the curing process is finished, the component carrier is cooled down. Due to the different CTEs of the single materials in the component carrier, stresses are introduced which finally cause a deformation and/or warpage of the component carrier.

The deformation of the component carrier makes further processing of the pressed panel (e.g. laser drilling) much more difficult. Thus, warpage has to be considered as one of the major obstacles for embedding processes.

In most of the cases, the component carrier (in the production format) is separated into arrays of a defined size, which feature the actual cards and which are surrounded by a frame area which does not feature any functional structures. The functional components are only embedded in the arrays of defined size, in the following called active areas. This results in a situation where inside the active area, the influence of the embedded chips pushes the average material properties towards a stiffer behavior with an overall, average lower CTE, while the rest of the laminate and the frame area still features the original material properties, i.e. an orthotropic behavior with higher CTEs in all directions. The higher the silicon ratio in the active area, the higher the properties delta between active area and laminate and frame area.

At cooling down after pressing, this results in a situation where the overall thermal shrinkage of the frame area is higher than the shrinkage of the active area and thus an in-plane pressure load is applied to the edges of the active area.

### BRIEF DESCRIPTION OF THE DRAWINGS

Below, embodiments are described in more detail with reference to the attached drawings.

FIG. 1 schematically shows a top view of a component carrier according to an embodiment.

FIGS. 2, 3, 4 and 5 schematically show a cross-sectional view of parts of a component carrier according to an embodiment.

FIG. 6 shows a flow diagram for simulating and optimizing a component carrier according to an embodiment.

The reference symbols used in the drawings, and their meanings, are listed in summary form in the list of reference symbols. In principle, identical parts are provided with the same reference symbols in the figures.

### DETAILED DESCRIPTION

Described herein are a component carrier for electronic components and to a method for optimizing the component carrier.

Especially for thin component carriers, low pressure loads can trigger a buckling warpage which might prevent the aforementioned further processing steps for the component carrier. In such cases, in particular, when a high number of semiconductor elements are present in an active area, it is difficult to find a distribution of dummy components, which reduces or prevents warpage.

It is a feature described herein to reduce the warpage of a component carrier during cooling down after pressing. It is a further feature to simplify and to enhance the reliability of the processing of a component carrier having a high number of embedded semiconductor elements distributed in an active area.

A first aspect relates to a component carrier. The component carrier may be designed for carrying electronic components. The component carrier may be a multi-layer panel and/or a multi-layer printed circuit board.

According to an embodiment, the component carrier comprises: a stack comprising a plurality of stacked layers, the stacked layers comprising at least one electrically conductive layer structure and at least one electrically insulating layer structure.

The stack may be seen as a substrate of the component carrier. The dimensions of the component carrier in direction of the stack and/or the stacking direction may be much smaller than in the extension direction of the layers, i.e. the layer direction. The extension in layer direction may be at least 100 times larger as in stacking direction. The layers may be aligned parallel to each other.

The at least one electrically conductive layer structure may comprise one or more electrically conducting layers, which may be made of metal. The at least one electrically insulating layer structure may comprise one or more electrically insulating layers, which may be made of plastics e.g. resin comprising polyepoxides and/or polyimides and/or ceramics. The electrically insulating layer structure may additionally comprise reinforcing material e.g. glass fibres and/or glass spheres. The electrically conducting layers and the electrically insulating layers may be alternatingly stacked. The electrically conducting layers may be structured to form electrically conducting paths and/or areas. The electrically conducting layers and/or the electrically insulating layers may be structured to form cavities for receiving components, such as semiconductor elements and dummy components.

According to an embodiment, the component carrier further comprises: a plurality of equally designed electronic units formed in the stack, each electronic unit comprising at least one semiconductor element embedded into the stack, wherein each semiconductor element is made of a semiconductor material.

In the end, after forming the component carrier, in some examples drilling holes and generating vias between different electrically conducting layers, each electronic unit may be cut out of the stack to form the final product, such as a circuit board providing a specific electronic functionality. Besides the at least one semiconductor element, the electronic units may comprise electrically conducting paths, formed in the electrically conducting layer structure, interconnecting the at least one semiconductor element with each other and/or with terminals on a surface of the electronic unit.

Each semiconductor element may be a semiconductor chip, i.e. a chip made of semiconductor material, such as doped silicon, and providing an electronic function. Each semiconductor element may be provided in a cavity in the stack.

According to an embodiment, at least a plurality of said electronic units are arranged to form at least one active area, which is surrounded by a frame area without functional components. In an active area, the electronic units are arranged side by side (in the direction perpendicular to the stack thickness) without a frame area between them. After cutting the component carrier into the electronic units, i.e. the final products, the frame area is disposed, i.e. is not used as final product.

According to an embodiment, the component carrier further comprises: a plurality of dummy components embedded into the stack in the frame area. The dummy components may be made of a material having a different coefficient of thermal expansion (CTE) as the stack and/or a different coefficient of thermal expansion as the electrically conducting layer structure and the electrically insulating layer structure and/or a different coefficient of thermal expansion as the frame. The dummy components may be passive components, i.e. do not have an electronic functionality. The dummy components may be made of the same semiconductor material as the semiconductor elements. For example, the dummy components are made of undoped silicon.

The average CTE of the frame area and/or the laminate is adjusted by embedding dummy components with defined properties, geometric features and/or sizes into the frame area. On an averaged level scale, the material behavior of the frame area and/or the laminate can be trimmed to meet the behavior of the active area. In such a way, a pressure load on the active area can be avoided and/or reduced, respectively. Thus, a local buckling at the active area as well as a resulting overall deformation of the component carrier can be significantly reduced.

According to an embodiment, the at least a plurality of said electronic units is arranged in the at least one active area in a pattern comprising more than 2 rows, for example 5 rows or more, and more than 2 columns or more, for example 5 columns. The dummy components are arranged around active areas comprising a high number of electronic units, such as at least more than 9, for example more than 25 electronic units.

It has been shown by performing simulations that, even when the active area, around which the dummy components are placed, is composed of a high amount of electronic units, also warpage can be significantly reduced. This effect may be enhanced by using dummy components of a larger size as the semiconductor elements.

According to an embodiment, each electronic unit comprises solely one semiconductor element, for example solely one semiconductor chip. An electronic unit may comprise a semiconductor chip and the electrically conducting paths interconnecting the semiconductor chip with itself and/or with terminals on a surface of the electronic unit. According to this embodiment the embedded semiconductor elements are strongly impacting the stack, due to the high portion of the material of the semiconductor elements with respect to the rest of the laminate. The resulting CTE mismatching is compensated by the plurality of dummy components, decreasing the warpage of the stack. Alternatively, an electronic unit may comprise at least two semiconductor chips and the electronically paths interconnecting the at least two semiconductor chips with themselves and/or with terminals on the surface of the electronic unit.

According to an embodiment, the at least one semiconductor element occupies at least more than at least 20%, in some examples at least 50%, of a volume of the corresponding electronic unit. Most of the volume of the electronic unit may be occupied by the one or more semiconductor elements. This may mean that the CTE of an electronic unit may be substantially influenced by the CTE of the semiconductor material of the at least one semiconductor element. In that case the plurality of dummy components, decrease the warpage of the stack affected by the high volume occupied by the semiconductor element.

According to an embodiment, the at least a plurality of said electronic units in an active area is equally spaced and/or distributed in the rows and/or columns. Each electronic unit may have a rectangular shape. The electronic units may be arranged in a rectangular pattern, wherein corresponding corners of neighboring electronic units have the same distance in row direction (equal to a width of an electronic unit) and the same distance in column direction (equal to a height of an electronic unit). In an example the distances in row direction and/or column direction may be in the nanometer range (1-1000 nm). In another example, the distances in row direction and/or column direction may be in the micrometer range (1-1000 μm). Yet in another example, the distances in row direction and/or column direction may be in the millimeter range (1-10 mm) or centimeter range (1-10 cm). This active area configuration where a huge amount of electronic units are provided, in combination with the provision of the semiconductor elements embedded into the stack, particularly impacts the warpage of the component carrier, said resulting warpage being at least partially prevented with the plurality of dummy components embedded into the stack.

According to an embodiment, a distance between two adjacent electronic units in the pattern is smaller than a width and/or thickness of the frame area. The frame area, which may have rectangular borders, may be wider than a single electronic unit. This allows for placing bigger and then more impacting dummy components in the frame area, which are larger than the semiconductor elements and/or the electronic units.

According to an embodiment, the dummy components are solely embedded into the frame area. No dummy components are provided in an active area. Vice versa, the semiconductor elements may be solely embedded in an active area and/or no semiconductor elements may be provided in the frame area. No dummy components are provided between two lines and/or rows of electronic units of the same active area. The CTE of an active area is solely influenced by semiconductor elements. THE CTE of the frame area is solely adjusted by the dummy components. This allow an easier adjustment of the impact in the warpage by the dummy components, the latter being not affected by neighboring other bodies.

According to an embodiment, at least some or all of the dummy components have an extension, in particular a planar surface extension, greater than an extension of the electronic units. The respective dummy components may have a width and/or height larger than a width and/or height of the electronic units. This may allow for reducing the number of dummy components compared to the number of semiconductor elements, which may reduce manufacturing efforts, such as placing the dummy components enhancing the estimation and the control of the warpage impact, as well as the manufacturing process adapted to add the dummy components.

According to an embodiment, an area of a dummy component is greater of at least 20 times, in some examples 100 times, the area of an electronic unit. Here, the surface area occupied by the component or unit, when viewing from above onto the component carrier, in particular from a point of view perpendicular to one of the main surfaces of the component carrier, may be meant. The CTE of the frame area may be adjusted to a CTE of the active area with much less dummy components as semiconductor elements. Moreover, the bigger the dummy component is, the higher is the impact to the warpage resulting from a huge amount of electronic units.

According to an embodiment, at least some of the dummy components have an extension, which is greater than a distance between neighboring electronic units of the at least a plurality of said electronic units.

This extension may refer to at least one between a planar extension of the dummy components, a smaller planar measure of the dummy components, the measure of a dummy component parallel to the measure orthogonal to two adjacent neighboring electronic units, a lateral measure of the dummy component parallel to the lateral extension of the two neighboring electronic units.

In particular, at least some of the dummy components may overlap at least one electronic unit completely, when viewed from the side, for example along the thickness direction of the stack. This may also stiffen the component carrier for preventing warpage.

According to an embodiment, the dummy components have different sizes. Extensions of the dummy components may vary, in particular in stacking direction and/or layer extension direction. The extensions also may vary in in row direction and/or column direction of the electronic units. In such a way, an average CTE may vary along the frame area. For example, an average CTE at a corner of a frame area may be different from an average CTE between such corners. The different sizes allow the use of specific dummy components for a specific frame portion, for example with specific dimension(s), in some examples with a specific width, this width in some examples defined by the distance between two adjacent active areas and/or between one active area and the adjacent border (edge) of the component carrier.

Also the following measures may allow for varying the CTE at different positions of the frame area, which may reduce warpage and/or buckling of the component carrier.

According to an embodiment, a dummy component occupies at least two layers of the stack. The cavity for a dummy component in the stack may be provided in several layers of the stack.

According to an embodiment, dummy components are arranged in at least two different layers of the stack. There may be dummy components, which occupy cavities, which extend along different layers in the stack.

According to an embodiment, dummy components are arranged in different layers as the semiconductor elements. Cavities for dummy components may be provided in different layers as cavities for semiconductor elements.

According to an embodiment, two dummy components are stacked with respect to each other within the stack. There may be at least one layer of the stack between the two dummy components. Depending on the needed impact of the dummy component, different positions also along the stack thickness can be provided.

According to an embodiment, two dummy components have different shapes. The shape of a dummy component may be a regular shape e.g. cube, a cylinder, a ball or a sphere. Alternatively the shape may be irregular. In the course of this document irregular shapes may comprise three dimensional forms having L-like, X-like, Y-like shapes. The use of dummy components having different shapes may reduce warpage and/or buckling of the component carrier.

According to an embodiment, at least one dummy component may be oriented in the component inclined with respect to a stack thickness direction and/or with respect to the electronic units of the active area. An angle of inclination may be between 10° and 80°, in some examples between 25° and 65°. The use of dummy components having inclined orientation in regard to electronic units of the active area may reduce warpage and/or buckling of the component carrier.

According to an embodiment, the dummy components are made of a homogenous material. Homogenous may mean that the dummy components do not have a substructure. Material properties, and in particular the CTE, do not vary between different positions inside a dummy component.

It may be that the dummy components are all made of the same material.

According to an embodiment, the dummy components are made of a material comprising silicon, such as undoped silicon. The dummy components may be made of the same silicon material as the semiconductor elements. This may help adjusting the CTE of the frame area to the CTE of the active area.

According to an embodiment, a coefficient of thermal expansion of the semiconductor elements differs at most by 10% from the coefficient of thermal expansion of at least some of the dummy components. Also this may help adjusting the CTE of the frame area to the CTE of the active area.

According to an embodiment, the at least one active area is rectangular. For example, the active area is composed of rectangular electronic units, which are arranged in a rectangular pattern. Such a pattern easily may be cut into the single electronic units with straight cuts. The adjacent rectangular electronic units may be in direct physical contact sharing one common surface. Alternatively the adjacent rectangular electronic unit may be distanced from each other.

According to an embodiment, the component carrier comprises a plurality of active areas, which are separated by strips composing the frame area. The component carrier may comprise at least two active areas, which are separated by the frame area. The frame area may have an outer border being the border of the component carrier and inner borders being the borders of the active areas. All these borders may be rectangular. The frame area may be composed of strips with parallel borders, which are connected at their ends.

According to an embodiment, the active areas are arranged in rows and/or columns. The frame area may comprise strips in row direction and/or column direction.

A further aspect relates to a method for optimizing a component carrier, such as described above and below. The method may be automatically performed by a computing device.

A further aspect relates to a computer program for optimizing a component carrier, which computer program, when being executed by a processor, is adapted to carry out the steps of the method as described above and below. The computer program may be executed in a computing device, such as a PC.

A further aspect relates to a computer-readable medium, in which such a computer program is stored. A computer-readable medium may be a hard disk, an USB (Universal Serial Bus) storage device, a RAM (Random Access Memory), a ROM (Read Only Memory), an EPROM (Erasable Programmable Read Only Memory) or a FLASH memory. A computer-readable medium may also be a data communication network, e.g. the Internet and/or a cloud storage, which allows downloading a program code. In general, the computer-readable medium may be a non-transitory or transitory medium.

According to an embodiment, the method comprises the steps of: providing a physical model of the component carrier, the physical model comprising a three-dimensional structure of the component carrier including the sizes and coefficients of thermal expansion of layers of the stack, the electronic units and the dummy components.

With the physical model, which may also comprise physical equations modelling the different materials, a heating and warpage, i.e. deformation due to different CTEs at different positions of the component carrier, may be determined. In particular, a behavior of the component carrier, when exposed to a specific temperature profile over time, can be determined.

The physical model also comprises a three-dimensional structure model of the component carrier, which includes sizes and positions of all its subcomponents, such as layers, cavities, semiconductor elements and dummy components.

According to an embodiment, the method comprises further the steps of: determining a warpage of the component carrier by simulating a cool down from a pressing temperature to an environmental temperature. An overall warpage may be determined from local warpages. For example, the overall warpage may be a maximum distance of a surface of the component carrier to a basis plane.

According to an embodiment, the method comprises further the steps of: minimizing the warpage by changing geometric properties and/or material properties of the dummy components in the physical model during an iterative optimization process, such that after each simulation, the warpage is reduced. After each simulation, the geometric properties and/or material properties of the dummy components may be changed, such that the warpage is further reduced. This may be a multidimensional optimization, wherein the parameters are the geometric properties and/or material properties. For example, optimization may be made by steepest descent, a Monte Carlo method and/or a genetic algorithm.

With this simulation, a distribution of dummy components may be found, which results in a component carrier with a warpage smaller than a desired value.

According to an embodiment, the geometric properties comprise sizes of the dummy components. The dummy components may be modelled as box-shaped elements with specific sizes in stacking direction and in layer extension direction, in particular row direction and column direction of the electronic units. With increasing size of the dummy components, the CTE of the frame area is adjusted towards the CTE of the dummy components.

According to an embodiment, the geometric properties comprise positions of the dummy components. For example, the distance to the border of the active area may be adjusted in this way. In particular, a distance between two neighboring dummy components also may be adjusted in this way. In the optimization process, the positions may be varied in layer extension direction and/or in stacking direction.

According to an embodiment, the geometric properties comprise a number of the dummy components. It also may be that additional dummy components are included into the physical model and/or removed from the physical model.

According to an embodiment, the geometric properties comprise a distribution pattern of the dummy components. For example, there may be constraints, for example, due to manufacturing reasons, that the dummy components have to equally be spaced and/or have to be aligned in a row and/or a column within a strip of the frame area.

According to an embodiment, the material properties comprise a coefficient of thermal expansion of the dummy components. The CTE of different dummy components may be different. For example, a list of possible CTEs for different materials may be included in the physical model.

According to an embodiment, the material properties comprise a material of the dummy components. The material of different dummy components also may be different. For example, materials with a direction dependent CTE may be chosen.

These and other aspects will be apparent from and elucidated with reference to the embodiments described hereinafter.

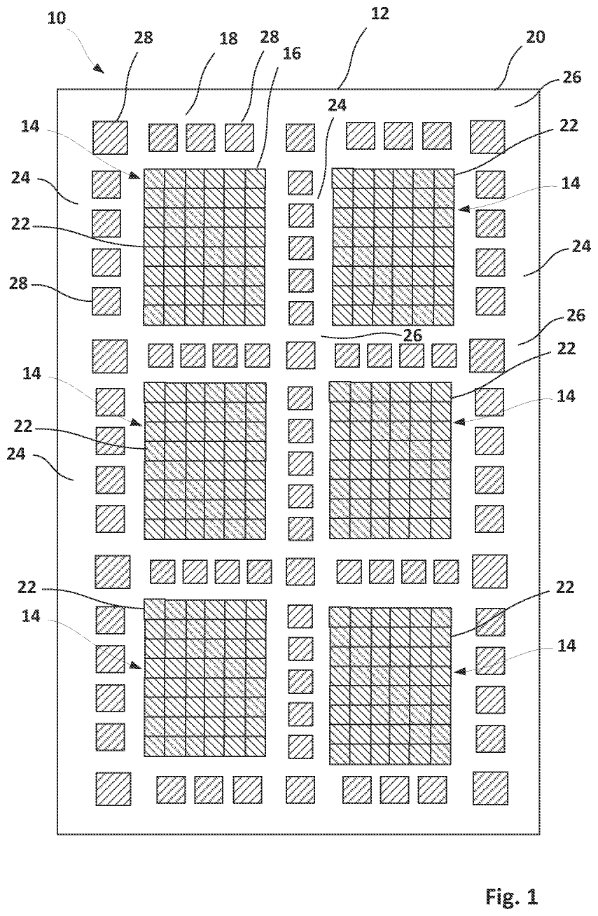

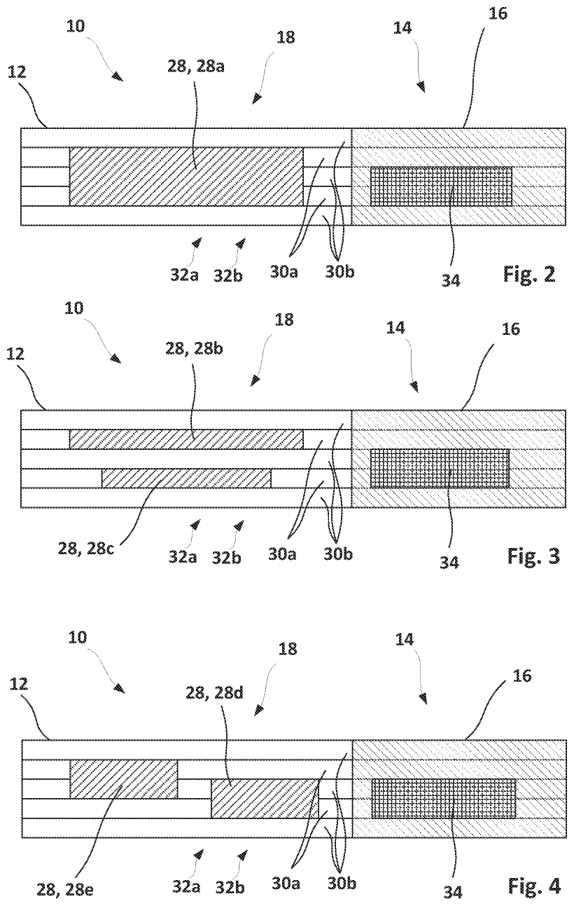

FIG. 1 shows a component carrier 10, which comprises a substrate and/or stack 12, which is composed of stacked layers (see FIGS. 2 to 5). The overall component carrier 10 has a rectangular shape.

The component carrier 10 is divided into active areas 14. Each active area 14 has a rectangular shape and the active areas 14 are arranged in rows and columns. Each active area 14 is composed of equally designed electronic units 16, which are also arranged in rows and columns in the active area 14. Solely one electronic unit 16 is provided with a reference numeral, however, every rectangle in FIG. 1 inside the active area is an electronic unit 16.

In each active area 14, the electronic units 16 are arranged in a pattern comprising more than 2 rows and more than 2 columns, in some examples more than 10 rows and more than 10 columns. The electronic units 16 in an active area 14 may be equally spaced and/or distributed in the rows and/or columns. A distance between two adjacent electronic units 16 in the pattern may be smaller than a width and/or thickness of the frame area 18.

The electronic units 16 comprise active components, such as conductor paths, electric and electronic components and in particular semiconductor elements (see FIGS. 2 to 5).

The area outside of the active areas 14 is a frame area 18, which has a rectangular outer border 20, which is also the border of the component carrier 10, and which has rectangular inner borders 22, which are also the borders of the active areas 14. The frame area 18 is composed of strips 24 besides the active areas 14 and of corner areas 26 interconnecting the strips. The strips 24 are aligned in row direction or column direction of the rows and columns of the active areas 14 and the electronic units 16. Solely some of the strips and corner areas are provided with reference numerals.

In the frame area 18, no functional components are included. However, dummy components 28 are embedded into the frame area 18 and in particular into the strips 24 and corner areas 26. Solely some of the dummy components 28 are provided with reference numerals, however, every rectangle in the frame area 18 depicts a dummy component 28.

The dummy components 28 are solely embedded into the frame area 18. The dummy components are made of a homogenous material, for example a material comprising silicon.

The dummy components 28 are arranged in rows and columns besides and between the active areas 14. It can be seen that there are dummy components 28 of different sizes and that different neighboring dummy components 28 may have different distances with respect to each other.

FIGS. 2 to 5 show cross sectional views through a part of a component carrier 10, such as the one shown in FIG. 1, which part comprises an electronic unit 16 and a dummy component 28.

The substrate and/or stack 12 comprises a plurality of stacked layers 30a, 30b, in particular electrically conducting layers 30a and electrically insulating layers 30b. The layers 30a, 30b are structured to form conducting paths and to form cavities, for example for the dummy components 28. In this way, the stacked layers 30a, 30b comprise at least one electrically conductive layer structure 32a and at least one electrically insulating layer structure 32b.

FIGS. 2 to 5 furthermore show that a semiconductor element 34 is embedded into an electronic unit 16. The layers 30a, 30b are structured for receiving the semiconductor element 34 and for electrically interconnecting the semiconductor element 34, for example with itself further semiconductor elements 34 in the electronic unit 16 and/or with terminals provided on a surface of the electronic unit 16.

It may be that the semiconductor element 34 occupies at least more than at least 20%, in some examples at least 50%, of a volume of the corresponding electronic unit 16.

The one or more semiconductor elements 34 of an electronic unit 16 are made of a semiconductor material, such as doped silicon. A coefficient of thermal expansion of the semiconductor elements 34 may differ at most by 10% from the coefficient of thermal expansion of at least some of the dummy components 28.

The dummy component 28 is embedded into the frame area 18 between layers 30a, 30b of the stack 12. It may be that the dummy component 28 has a size in stacking direction, which is larger than one, two or more layers 30a, 30b and/or that the dummy component 28 spans more than one layer.

FIG. 2 shows that a single dummy component 28 is embedded into the stack 12, which has a larger size in stacking direction as the semiconductor element 34. Furthermore, the dummy component 28 is embedded in different layers 30a, 30b as the semiconductor element 34.

FIG. 3 shows that dummy components 28b, 28c, for example of different sizes in stacking direction and/or in surface extension direction (and/or row and column direction), may be embedded stacked with each other. It also may be that the dummy components 28b, 28c are embedded in solely one layer 30a, 30b. One or more layers 30a, 30b may be arranged between the dummy components 28b, 28c.

The dummy components 28b, 28c may overlap each other, when viewed from above in stacking direction.

FIG. 4 shows that dummy components 28d, 28e, for example of different sizes in stacking direction and/or in surface extension direction (and/or row and column direction), may be embedded in different layers 30a, 30b. The dummy components 28d, 28e may overlap each other, when viewed from besides in surface extension direction.

In general, the dummy components 28 may be distributed in the frame area 18 in the following ways: A dummy component 28a, 28d, 28e may occupy at least two layers 30a, 30b of the stack 12. Dummy components 28b, 28c, 28d, 28e may be arranged in at least two different layers 30a, 30b of the stack 12. Dummy components 28 may be arranged in different layers 30a, 30b as the semiconductor elements 34. Two dummy components 28b, 28c may be stacked with respect to each other within the stack 12.

FIG. 5 shows that dummy components 28f, 28g may have different shapes. The shapes may be box-shaped, sphere- or ellipsoid-shaped or irregular shaped. Furthermore, at least one dummy component 28g may be oriented in the component inclined with respect to a stack thickness direction and/or with respect to the electronic units 16 of the active area 14.

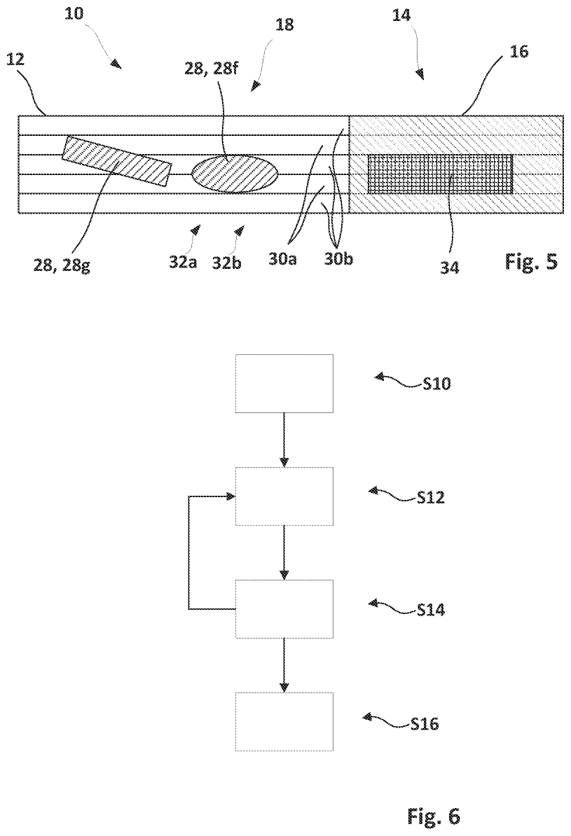

FIG. 6 shows a flow diagram for a method for optimizing and optionally manufacturing a component carrier 10.

In step S10, a physical model of the component carrier 10 is defined. In a first sub-step, fixed components of the component carrier 10, such as the stack 12, the layer structures 32a, 32b, the electronic units 16, with their internal structure together with the semiconductor elements 34 are included into the physical model 36.

In the physical model, geometric properties, such as position and sizes, and physical properties, such as CTE and thermal conductivity, of these components are included. These parameters are not varied in the optimization process described below and are considered as fixed parameters.

In a second sub-step, the active areas 14 and the frame area 18 are identified. This may be done automatically, by identifying functional components and including them into an active area 14, when their distance is smaller than a threshold. The frame area 18 may be the area of the component carrier being a non-functional area and/or outside of the active areas 14.

In a third sub-step, dummy components 28 are placed into the frame area 18. This also may be done automatically.

For example, strips 24 and/or corner areas 26 of the frame area 18 may be identified and specific patterns of dummy components may be placed there. Such patterns may comprise lines of dummy components of specific sizes and/or distances.

It also may be that the dummy components are placed at random places or that a specific number of dummy components of specific sizes is distributed in the frame area 18 dependent on distances to the borders 20, 22 and optionally that their distances are maximized.

In step S10, a physical model of the component carrier 10 is provided. The physical model comprises a three-dimensional structure of the component carrier 10 including the sizes and coefficients of thermal expansion of layers 30a, 30b of the stack 12, the electronic units 16 and the dummy components 28.

In step S12, a cool down from a pressing temperature, such as more than 100° C., to an environmental temperature, such as below 30° C., is simulated. The simulation is started with a flat component carrier 10 and based on the different CTEs of the components in the physical model, a warpage of the component carrier 10 is determined.

Such a simulation may be performed with a finite elements method.

In step S14, in a first sub-step, a warpage value of the component carrier 10 is determined. For example, the warpage value, which is indicative of the amount of warpage, may be a maximal distance of a surface from the component carrier 10 from a middle plane. The warpage value also may be a maximal curvature of a surface and/or layer 30a, 30b of the component carrier 10.

In a second sub-step of step S14, geometric properties and/or material properties of the dummy components 28 are changed. These properties are changed, such that the warpage and in particular the warpage value is likely to be reduced.

For example, sizes of the dummy components 28, positions of the dummy components 28, orientations of the dummy components 28, shapes of the dummy components 28, a number of the dummy components 28 and/or a distribution pattern of the dummy components 28 may be changed. Also, a coefficient of thermal expansion of the dummy components and/or a material of the dummy components 28 may be changed.

All these geometric properties and material properties, which may be seen as variable parameters, may be automatically changed to reduce the warpage.

The method returns to step S12 and simulates the component carrier 10 again with the changed geometric properties and/or material properties.

By doing this iteratively, the warpage may be minimized automatically. The iterative optimization process may be a multi-dimensional optimization process, in the space of geometric properties and/or material properties. For finding new values for the geometric properties and/or material properties, a steepest descent method, Monte Carlo method or a genetic algorithm may be used.

In optional step S16, the component carrier 10, as optimized in the previous steps, may be manufactured. Additionally dummy components 28, such as determined in the optimized physical model, are placed in the component carrier 10. The component carrier 10 is pressed and cooled down. The resulting component carrier 10 has a reduced warpage and may be further processed, such as drilled and/or cut more easily.

The applicant has performed a lot of simulations and has found that for a component carrier 10 having active areas 14 with a high number of electronic units 16, the following properties of dummy components 28 result in a low warpage.

At least some of the dummy components 28 have an extension greater than an extension of the electronic units 16. An area of a dummy component 28 is greater of at least 20 times, in some examples 100 times, the area of an electronic unit 16.

At least some of the dummy components 28 have an extension, which is greater than a distance between neighboring electronic units 16 of an active area 14.

While the embodiments described herein have been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art and practicing the claimed invention, from a study of the drawings, the disclosure, and the appended claims. In the claims, the word “comprising” does not exclude other elements or steps, and the indefinite article “a” or “an” does not exclude a plurality. A single processor or controller or other unit may fulfil the functions of several items recited in the claims. The mere fact that certain measures are recited in mutually different dependent claims does not indicate that a combination of these measures cannot be used to advantage. Any reference signs in the claims should not be construed as limiting the scope.

### LIST OF REFERENCE SYMBOLS

10 component carrier
12 substrate, stack
14 active area
16 electronic unit
18 frame area
20 outer border
22 inner border
24 strip
26 corner area
28 dummy component
28a dummy component
28b dummy component
28c dummy component
28d dummy component
28e dummy component
28f dummy component
28g dummy component
30a electrically conducting layer
30b electrically insulating layer
32a electrically conductive layer structure
32b electrically insulating layer structure
34 semiconductor element

What is claimed is:

1. A component carrier, comprising:
a stack comprising a plurality of stacked layers, the stacked layers comprising at least one electrically conductive layer structure and at least one electrically insulating layer structure;
a plurality of equally designed electronic units formed in the stack, each electronic unit comprising at least one semiconductor element embedded into the stack, wherein each semiconductor element is made of a semiconductor material;
wherein at least a plurality of said electronic units are arranged to form at least one active area, which is surrounded by a frame area without functional components;
a plurality of dummy components embedded into the stack in the frame area;
wherein the at least a plurality of said electronic units is arranged in the at least one active area in a pattern comprising more than 2 rows and more than 2 columns.

2. The component carrier of claim 1,
wherein each electronic unit comprises solely one semiconductor element.

3. The component carrier of claim 1,
wherein the at least one semiconductor element occupies at least more than at least 20% of a volume of the corresponding electronic unit.

4. The component carrier of claim 1,
wherein the at least a plurality of said electronic units in an active area are equally spaced and/or distributed in the rows and/or columns; and/or
wherein a distance between two adjacent electronic units in the pattern is smaller than a width and/or thickness of the frame area.

5. The component carrier of claim 1,
wherein the dummy components are solely embedded into the frame area.

6. The component carrier of claim 1,
wherein at least some of the dummy components have an extension greater than an extension of the electronic units.

7. The component carrier of claim 1,
wherein an area of a dummy component is greater of at least 20 times the area of an electronic unit.

8. The component carrier of claim 1,
wherein at least some of the dummy components have an extension, which is greater than a distance between neighboring electronic units of the at least a plurality of said electronic units.

9. The component carrier of claim 1,
wherein the dummy components have different sizes.

10. The component carrier of claim 1,
wherein a dummy component occupies at least two layers of the stack.

11. The component carrier of claim 1,
wherein dummy components are arranged in at least two different layers of the stack.

12. The component carrier of claim 1,
wherein dummy components are arranged in different layers as the semiconductor elements; and/or
wherein two dummy components are stacked with respect to each other within the stack.

13. The component carrier of claim 1,
wherein two dummy components have different shapes; and/or
wherein at least one dummy component may be oriented in the component inclined with respect to a stack thickness direction and/or with respect to the electronic units of the active area.

14. The component carrier of claim 1,
wherein the dummy components are made of a homogenous material.

15. The component carrier of claim 1,
wherein the dummy components are made of a material comprising silicon.

16. The component carrier of claim 1,
wherein a coefficient of thermal expansion of the semiconductor elements differs at most by 10% from the coefficient of thermal expansion of at least some of the dummy components.

17. The component carrier of claim 1,
wherein the at least one active area is rectangular; and/or
wherein the component carrier comprises a plurality of active areas, which are separated by strips composing the frame area; and/or
wherein the active areas are arranged in rows and/or columns.

18. A method for optimizing a component carrier;
the component carrier comprising a stack comprising a plurality of stacked layers, the stacked layers comprising at least one electrically conductive layer structure and at least one electrically insulating layer structure; a plurality of equally designed electronic units formed in the stack, each electronic unit comprising at least one semiconductor element embedded into the stack, wherein each semiconductor element is made of a semiconductor material; wherein at least a plurality of said electronic units is arranged to form at least one active area, which is surrounded by a frame area without functional components; a plurality of dummy components embedded into the stack in the frame area; wherein the at least a plurality of said electronic units is arranged in the at least one active area in a pattern comprising more than 2 rows and more than 2 columns;
the method comprising:
providing a physical model of the component carrier, the physical model comprising a three-dimensional structure of the component carrier including sizes and coefficients of thermal expansion of layers of the stack, the electronic units and the dummy components;
determining a warpage of the component carrier by simulating a cool down from a pressing temperature to an environmental temperature;
minimizing the warpage by changing geometric properties and/or material properties of the dummy components in the physical model during an iterative optimization process, such that after each simulation, the warpage is reduced.

19. The method of claim 18,
wherein the geometric properties of the dummy components comprise at least one of:
sizes of the dummy components;
positions of the dummy components;
a number of the dummy components; or
a distribution pattern of the dummy components.

20. The method of claim 18, wherein the material properties comprise at least one of:
a coefficient of thermal expansion of the dummy components; or
a material of the dummy components.
